(19) United States
(12) Patent Application Publication
(10) Pub. No.: US 2023/0198453 A1
(43) Pub. Date: Jun. 22, 2023

(54) SOLAR POWER GENERATION ASSEMBLY WITH INTEGRATED MOUNTING AND WATER MANAGEMENT AND METHOD FOR PROVIDING SAME

(71) Applicant: TOTALENERGIES ONETECH, Solaize Cedex (FR)

(72) Inventors: Alexander F. KELLER, Boston, MA (US); Laurence B. MACKLER, Corte Madera, CA (US)

(73) Assignee: TOTALENERGIES ONETECH, Solaize Cedex (FR)

(21) Appl. No.: 18/169,574

(22) Filed: Feb. 15, 2023

Related U.S. Application Data
(63) Continuation of application No. 15/885,053, filed on Jan. 31, 2018, now abandoned.
(60) Provisional application No. 62/462,963, filed on Feb. 24, 2017.

(51) Int. Cl. H02S 20/10; H01L 31/048; H01L 31/052; H02S 20/23; H02S 40/34; H02S 30/10; F24S 25/35; H02S 40/36; F24S 25/12; F24S 25/37; F24S 40/44

(52) U.S. Cl. CPC H02S 20/10; H01L 31/048; H01L 31/0521; H02S 20/23; H02S 40/34; H02S 30/10; F24S 25/35; H02S 40/36; F24S 25/12; F24S 25/37; F24S 40/44; Y02E 10/50; F24S 2025/014

(57) ABSTRACT

A solar power generation assembly includes a first canopy wing positioned at a first predetermined inclination and a second canopy wing positioned at a second predetermined inclination, wherein the first and second canopies form a dual-incline structure and a main gutter is disposed between the first and second canopies. Additionally, at least one mounting rail gutter extends perpendicular to the main gutter and a secondary gutter extends parallel to the main gutter, wherein the secondary gutter directs precipitation to the mounting rail gutter and the mounting rail gutter directs precipitation into the main gutter, wherein the secondary gutter, the mounting rail gutter, and the main gutter are configured to provide both mounting and precipitation management functionality to the solar power generation assembly.

### CROSS-REFERENCE TO RELATED APPLICATION

This application is a continuation of U.S. application Ser. No. 15/885,053, filed on Jan. 31, 2018 which claims the benefit of U.S. Provisional Application No. 62/462,963, filed Feb. 24, 2017, which is herein incorporated by reference in their entirety.

### BACKGROUND

### 1. Field of the Invention

The present disclosure relates to a solar power generation assembly and methods for providing the same.

### 2. Description of the Related Art

To reduce dependence on fossil fuels (both domestic and imported) and reduce the negative environmental impacts of such fuel emissions, there is a need to increase the distributed power generation base. Similarly, there is a need to maximize the value and productivity of single-use real estate to facilitate such things as mounting for PV or solar modules, shade for cars, shade for outdoor activities and other events and purposes. Complications and limitations associated with rooftop installations make incorporating solar power generation systems in underutilized open spaces one such means of addressing these needs. This will necessitate an increase of the electrical transmission infrastructure.

Conventional support structures for PV power systems are typically designed such that the module arrays are oriented along a single slope plane. Several drawbacks of these structures are limited sight lines from beneath the structures, avalanching of snow and ice from the system, and difficulty of deployment on parking lots that are not ideally geographically oriented.

Many arrangements have been proposed, but in general the currently available support structures for solar power generation do not integrate mounting and water management features. A need exists for protective structures/systems that shelter from snow, rain, and other precipitation. Accordingly, there is a need for an improved solar power generation assembly and methods for providing the same.

### SUMMARY

The foregoing paragraphs have been provided by way of general introduction, and are not intended to limit the scope of the following claims. The described embodiments, together with further advantages, will be best understood by reference to the following detailed description taken in conjunction with the accompanying drawings.

Aspects of the disclosed subject matter relate to a solar power generation assembly and method for providing the same involving an array of solar generation modules on an inclined structure (e.g. single incline structure, dual-incline structure) which can achieve high energy yields over a wide range of azimuths/orientations.

According to embodiments of the disclosed subject matter, a solar power generation assembly includes a first canopy wing positioned at a first predetermined inclination and a second canopy wing positioned at a second predetermined inclination, wherein the first and second canopies form a dual-incline structure and a main gutter is disposed between the first and second canopies. Additionally, at least one mounting rail gutter extends perpendicular to the main gutter and a secondary gutter extends parallel to the main gutter, wherein the secondary gutter directs precipitation to the mounting rail gutter and the mounting rail gutter directs precipitation into the main gutter, wherein the secondary gutter, the mounting rail gutter, and the main gutter are configured to provide both mounting and precipitation management functionality to the solar power generation assembly.

In one embodiment, a solar power generation assembly includes a first support structure, a main gutter extending along a first longitudinal axis, and a first mounting structure extending in a first plane above a ground surface, the first mounting structure being supported above the ground surface by the first support structure, wherein the first mounting structure comprises at least one mounting rail gutter extending perpendicular to the main gutter in the first plane. Additionally, the solar power generation assembly includes a first array includes a plurality of solar modules, the first array being coupled to the first mounting structure, at least one module clip for mounting at least one of the plurality of solar modules on the mounting rail gutter, the module clip being configured for installation from an underside of the solar module, and a secondary gutter extending perpendicular to the main gutter in the first plane, the secondary gutter being positioned between adjacent solar modules of the plurality of solar modules, wherein the secondary gutter directs precipitation to the mounting rail gutter and the mounting rail gutter directs precipitation into the main gutter, wherein the secondary gutter, the mounting rail gutter, and the main gutter are configured to provide both mounting and precipitation management functionality to the solar power generation assembly.

In one embodiment, a method for providing a solar power generation assembly includes providing at least one fastener into a fastener channel at an underside of a mounting rail gutter, wherein the mounting rail gutter extends perpendicular to a main gutter in a first plane; attaching the mounting rail gutter to a first support structure from the underside of the solar power generation assembly, wherein the first support structure supports a first mounting structure extending in the first plane; attaching a secondary gutter to the mounting rail gutter from the underside of the solar power generation assembly, wherein the secondary gutter extends parallel to the main gutter in the first plane; attaching at least one module clip to at least one of a plurality of solar modules configured in a first array, wherein the first array of solar modules is coupled to the first mounting structure; and mounting the first array of solar modules above the mounting rail gutter and the secondary gutter from the underside of the solar power generation assembly with the at least one module clip, wherein the secondary gutter directs precipitation to the mounting rail gutter and the mounting rail gutter directs precipitation into the main gutter, wherein the secondary gutter, the mounting rail gutter, and the main gutter are configured to provide both mounting and water management functionality to the solar power generation assembly.

### BRIEF DESCRIPTION OF THE DRAWINGS

A more complete appreciation of the disclosure and many of the attendant advantages thereof will be readily obtained as the same becomes better understood by reference to the following detailed description when considered in connection with the accompanying drawings, wherein:

FIG. 1 depicts a solar power generation assembly according to one or more aspects of the disclosed subject matter;

FIG. 2A depicts an aerial view of a solar power generation assembly with solar modules in a landscape configuration according to one or more aspects of the disclosed subject matter;

FIG. 2B depicts an aerial view of a solar power generation assembly with solar modules in a portrait configuration according to one or more aspects of the disclosed subject matter;

FIG. 3A depicts layers of a solar power generation assembly with solar modules in a portrait configuration according to one or more aspects of the disclosed subject matter;

FIG. 3B depicts layers of a solar power generation assembly with solar modules in a landscape configuration according to one or more aspects of the disclosed subject matter;

FIG. 4A depicts assembly parts of a solar power generation assembly according to one or more aspects of the disclosed subject matter;

FIG. 4B depicts assembly parts of a solar power generation assembly according to one or more aspects of the disclosed subject matter;

FIG. 5 depicts assembly parts of a solar power generation assembly according to one or more aspects of the disclosed subject matter;

FIG. 6A depicts an aerial view of a solar power generation assembly with solar modules in a portrait configuration according to one or more aspects of the disclosed subject matter;

FIG. 6B depicts an aerial view of a solar power generation assembly with solar modules in a landscape configuration according to one or more aspects of the disclosed subject matter;

FIG. 7A depicts an underside view of components of a solar power generation assembly according to one or more aspects of the disclosed subject matter;

FIG. 7B depicts an underside view of components of a solar power generation assembly according to one or more aspects of the disclosed subject matter;

FIG. 8A depicts an underside view of components of a solar power generation assembly according to one or more aspects of the disclosed subject matter;

FIG. 8B depicts an underside view of components of a solar power generation assembly according to one or more aspects of the disclosed subject matter;

FIG. 9A depicts a side view of components of a solar power generation assembly according to one or more aspects of the disclosed subject matter;

FIG. 9B depicts a side view of components of a solar power generation assembly according to one or more aspects of the disclosed subject matter;

FIG. 10A depicts a side view of components of a solar power generation assembly according to one or more aspects of the disclosed subject matter;

FIG. 10B depicts a side view of components of a solar power generation assembly according to one or more aspects of the disclosed subject matter;

FIG. 11A depicts a side view of components of a solar power generation assembly according to one or more aspects of the disclosed subject matter;

FIG. 11B depicts a side view of components of a solar power generation assembly according to one or more aspects of the disclosed subject matter;

FIG. 12 depicts a side view and two cross-sectional views of a rail gutter according to one or more aspects of the disclosed subject matter;

FIG. 13A depicts various perspective views of a module clip according to one or more aspects of the disclosed subject matter;

FIG. 13B depicts various perspective views of a module clip according to one or more aspects of the disclosed subject matter;

FIG. 14A depicts a secondary gutter according to one or more aspects of the disclosed subject matter;

FIG. 14B depicts a secondary gutter according to one or more aspects of the disclosed subject matter;

FIG. 15 depicts a whip guide according to one or more aspects of the disclosed subject matter;

FIG. 16A depicts operations for calculating and designing a drainable area of a solar power generation assembly according to one or more aspects of the disclosed subject matter;

FIG. 16B depicts operations for calculating and designing a drainable area of a solar power generation assembly according to one or more aspects of the disclosed subject matter;

FIG. 17A depicts operations for calculating and designing a drainable area of a solar power generation assembly according to one or more aspects of the disclosed subject matter;

FIG. 17B depicts operations for calculating and designing a drainable area of a solar power generation assembly according to one or more aspects of the disclosed subject matter;

FIG. 18 depicts operations of assembling a solar power generation assembly according to one or more aspects of the disclosed subject matter;

FIG. 19 depicts operations of assembling a solar power generation assembly according to one or more aspects of the disclosed subject matter;

FIG. 20 depicts operations of assembling a solar power generation assembly according to one or more aspects of the disclosed subject matter;

FIG. 21 depicts operations of assembling a solar power generation assembly according to one or more aspects of the disclosed subject matter;

FIG. 22 depicts operations of assembling a solar power generation assembly according to one or more aspects of the disclosed subject matter;

FIG. 23 depicts operations of assembling a solar power generation assembly according to one or more aspects of the disclosed subject matter;

FIG. 24 depicts operations of assembling a solar power generation assembly according to one or more aspects of the disclosed subject matter; and

FIG. 25 depicts operations of assembling a solar power generation assembly according to one or more aspects of the disclosed subject matter.

### DETAILED DESCRIPTION

The following detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

This specification includes references to “one embodiment” or “an embodiment.” The appearances of the phrases “in one embodiment” or “in an embodiment” do not necessarily refer to the same embodiment. Particular features, structures, or characteristics may be combined in any suitable manner consistent with this disclosure.

Terminology. The following paragraphs provide definitions and/or context for terms found in this disclosure (including the appended claims):

“Comprising.” This term is open-ended. As used in the appended claims, this term does not foreclose additional structure or steps.

“Configured To.” Various units or components may be described or claimed as “configured to” perform a task or tasks. In such contexts, “configured to” is used to connote structure by indicating that the units/components include structure that performs those task or tasks during operation. As such, the unit/component can be said to be configured to perform the task even when the specified unit/component is not currently operational (e.g., is not on/active). Reciting that a unit/circuit/component is “configured to” perform one or more tasks is expressly intended not to invoke 35 U.S.C. § 112, sixth paragraph, for that unit/component.

“First,” “Second,” etc. As used herein, these terms are used as labels for nouns that they precede, and do not imply any type of ordering (e.g., spatial, temporal, logical, etc.). For example, reference to a “first” motor drive does not necessarily imply that this motor drive is the first motor drive in a sequence; instead the term “first” is used to differentiate this motor drive from another motor drive (e.g., a “second” motor drive).

“Coupled”—The following description refers to elements or nodes or features being “coupled” together. As used herein, unless expressly stated otherwise, “coupled” means that one element/node/feature is directly or indirectly joined to (or directly or indirectly communicates with) another element/node/feature, and not necessarily mechanically.

In addition, certain terminology may also be used in the following description for the purpose of reference only, and thus are not intended to be limiting. For example, terms such as “upper,” “lower,” “above,” “below,” “in front of,” and “behind” refer to directions in the drawings to which reference is made. Terms such as “front,” “back,” “rear,” “side,” “outboard,” “inboard,” “leftward,” and “rightward” describe the orientation and/or location of portions of a component, or describe the relative orientation and/or location between components, within a consistent but arbitrary frame of reference which is made clear by reference to the text and the associated drawings describing the component(s) under discussion. Such terminology may include the words specifically mentioned above, derivatives thereof, and words of similar import.

“Inhibit”—As used herein, inhibit is used to describe a reducing or minimizing effect. When a component or feature is described as inhibiting an action, motion, or condition it may completely prevent the result or outcome or future state completely. Additionally, “inhibit” can also refer to a reduction or lessening of the outcome, performance, and/or effect which might otherwise occur. Accordingly, when a component, element, or feature is referred to as inhibiting a result or state, it need not completely prevent or eliminate the result or state.

A solar power generation assembly or Building Integrated photovoltaic (BIPV) racking system with integrated mounting and water management features is disclosed herein. Additionally, a method for providing the solar power generation assembly is disclosed. The solar or photovoltaic (PV) racking system can comprise mounting rails which also function as gutters and attachment points for various components like braces, mini gutters, and clips for solar modules or panels. Further, a method for assembling a solar power generation assembly or system from the underside of the assembly is disclosed. Mounting clips can be assembled to PV panels on the ground and allow them to be attached to the mounting rails from beneath the assembly or system.

Reference will now be made in detail to several embodiments of the invention that are illustrated in the accompanying drawings. Wherever possible, same or similar reference numerals are used in the drawings and the description to refer to the same or like parts or steps.

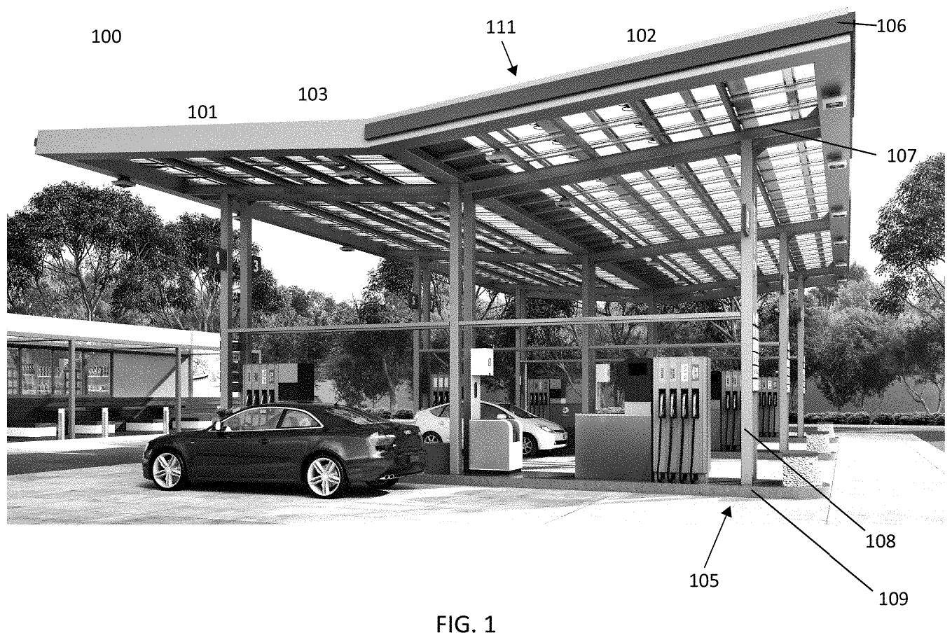

FIG. 1 depicts a solar power generation assembly 100 (which may be referred to as system 100) according to one embodiment. In the example, the solar power generation assembly 100 is provided as a service station, however solar power generation assemblies and systems described herein can be used for any desirable application, for example a carport, a canopy for shade or otherwise, a garage or any other functional and/or aesthetic structure. For ease of description, solar power generation assemblies for use as a service station having a dual-incline canopy are depicted, however numerous other applications are also possible without departing from the scope of this invention.

Solar power generating assembly 100 can comprise a first support structure 105 and a first mounting structure 111 extending in a first plane above a ground surface. The first mounting structure 111 can be supported above the ground surface by the first support structure 105.

In some embodiments, solar power generating assemblies or systems can comprise one or more canopy wings providing for a single or dual-incline structure. Depending on specifications, canopy wings can differ in length, width, and/or angle of inclination. As an illustrative example, solar power generating assembly 100 comprises one or more support structures 105 to or on which a canopy wing A 101 and a canopy wing B 102 are attached or disposed, directly or indirectly. Canopy wing A 101 and/or canopy wing B 102 can be curved or flat. The lengths of the canopy wings may be equal or different and are typically adjusted to improve the energy yield of the of the assembly or system 100 subject to the location of the installation site, the orientation of the installation, customer preferences, local zoning limitations, structural considerations, the incline angles, and other conditions that may exist at the installation site.

The assembly or system 100 may or may not be connected to the public electrical grid or may be connected directly to the owner's electrical system or may be used to power elements connected directly to the assembly or system 100. Assembly or system 100 may be located in fueling stations, open areas, parks, sidewalks, parking lots, roadways, sidewalks, parks, campuses, watersheds, reservoirs, canals, gathering places for education and/or entertainment, transportation nodes, and other uses.

Each canopy wing A 101 or canopy wing B 102 can comprise and/or be supported by one or more purlins and/or or transverse support beams 107. Support structure 105 can further comprise one or more vertical support columns 108 and further consist of, be disposed on or supported by foundation piers and/or footings 109. In the example of FIG. 1, three in-plane support columns are provided (a central support beam, a first peripheral support beam at canopy wing 101 and second peripheral support beam at canopy wing 102). However, in other embodiments a single central support beam can be provided, as one of ordinary skill would recognize. Piers and/or footings may be made of concrete or other adequate foundation material subject to local requirements, structural considerations, seismic considerations, and other requirements and preferences.

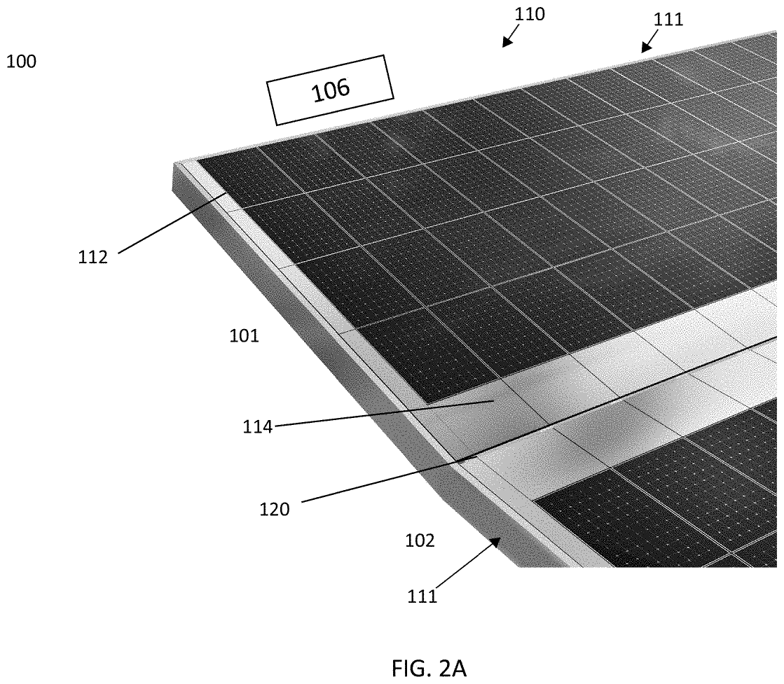

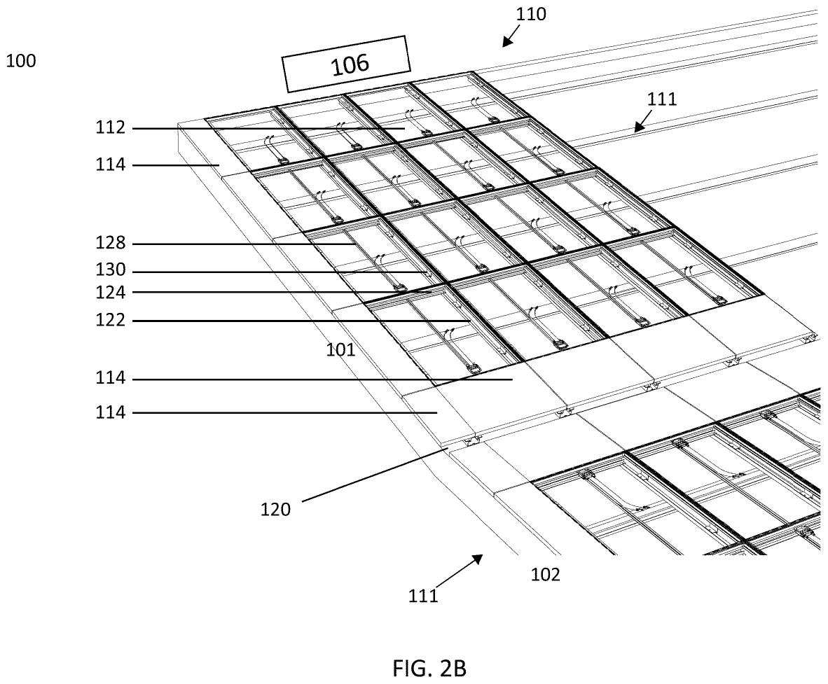

As depicted in the top down perspective view of FIG. 2A-2B, each canopy wing A 101 and canopy wing B 102 can comprise a mounting structure 111 to which an array 110 is attached. Array 110 can comprise energy producing (photovoltaic or other) modules 112 and/or non-energy-producing, decorative or “filler” modules or panels (e.g. decorative modules which are transparent or translucent, with or without decorative designs). As depicted in FIG. 2, array 110 comprises PV modules 112 (e.g. laminated crystalline silicon solar cells, photovoltaic thin films or any other energy producing material) and filler panels 114. PV modules 112 can comprise an electrical or junction box 115 and electrical whips 113 having connectors 113′. Photovoltaic elements may be made of monocrystalline silicon, polycrystalline silicon, amorphous silicon, copper-indium-gallium-selenide (CIGS), thin film, or any other photovoltaic technology. The array 110 may also be a passive or active solar thermal system. The array 110 may also include lighting or heating elements, solar thermal elements, and may include a wide range of structures including pumps, water storage containers and other elements for water collection and drainage. System 100 can also include structures for fans, pumps, tubing, elements for cooling such as spray misters, fans, skylights, antennas, cellular repeaters, illuminated panels, phosphorescent or similar panels to provide passive nighttime illumination, and other structures as may be suitable and desired. System 100 may also include signage, inverters, combiner boxes, sub-combiner boxes, direct current shutoff boxes, junction boxes, acoustical control panels, hydrogen production and/or storage devices. In some embodiments such as depicted in FIGS. 2A and 2B, assembly or system 100 can comprise decorative elements and/or signage 106 (for advertising or design purposes).

Some applications may require a substantially watertight assembly or system such that water leaking from the top 103 of the assembly 100 to areas underneath 104 the assembly 100 are inhibited or prevented. Furthermore, the ability to install the assembly 100, mounting structure 111 and/or array 110 from underneath may be significantly more advantageous or even required by some applications. Other assemblies and associated assembly methods can necessitate installers to install an array from the top of the assembly which can be unsafe or otherwise undesirable. Disposed between canopy wing A 101 and canopy wing B 102 is a main drainage cavity or gutter 120 through which water, ice, melting snow and other elements can pass. Additional features of the water management approach of assemblies described herein will be described in more detail below.

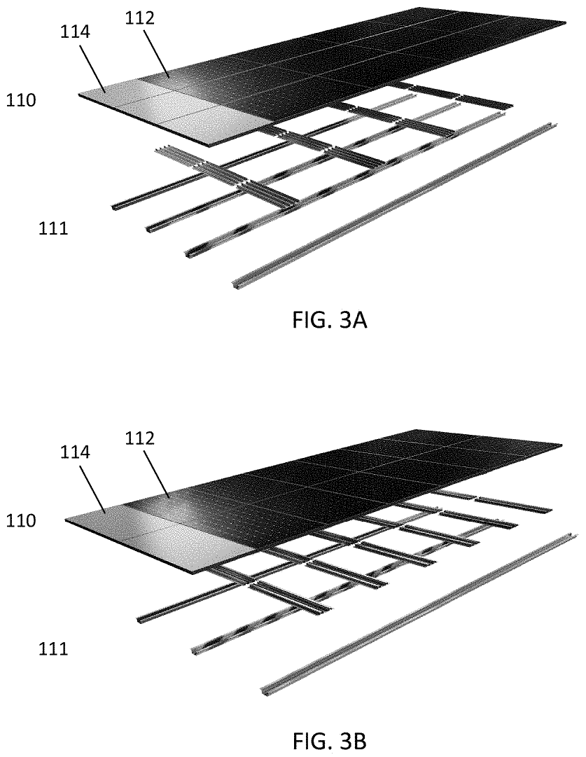

The array 110 and mounting structure 111 of assembly or system 100 can be provided in any desirable configuration. In the example of FIGS. 2A and 3A, array 110 comprises PV modules 112 arranged in a “portrait” configuration such that the longest dimension of the PV modules 112 are parallel to central or main gutter 120. As another example described herein, PV modules 112 can be arranged in a “landscape” configuration such that the longest dimension of the PV modules 112 are perpendicular to central or main gutter 120 such as depicted in FIG. 2B and FIG. 3B. To display the versatility of the assemblies described herein, both configurations are presented. Unless otherwise specified, the numerical indicators used to refer to components in Figures denoted with “A” (depicting “portrait”-oriented PV modules) are similar to those used to refer to components or features in Figures denoted with “B” (depicting “landscape”-oriented PV modules). As yet another example, PV modules or panels can be substantially square such that a particular orientation is irrelevant and the assembly can be installed accordingly.

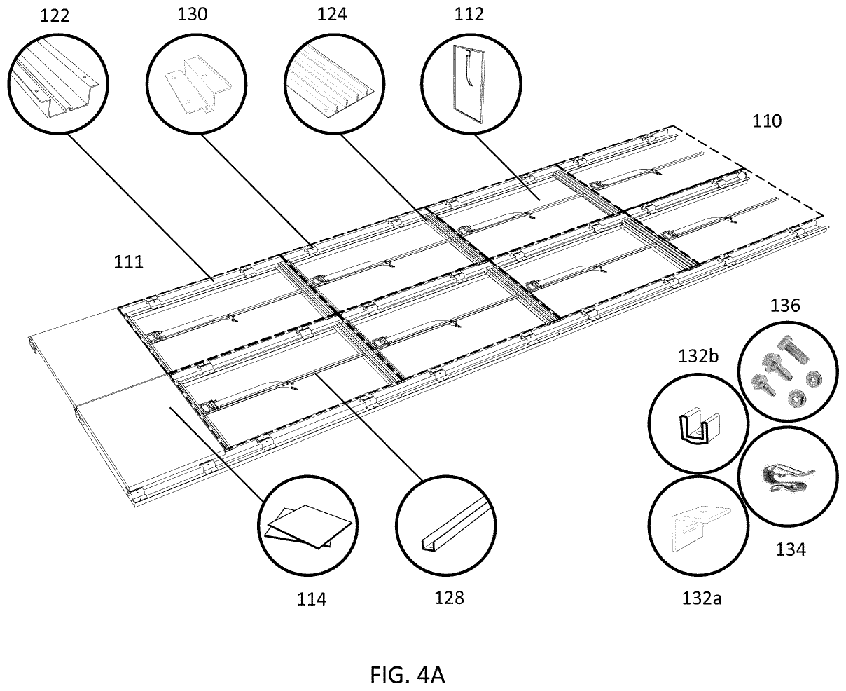

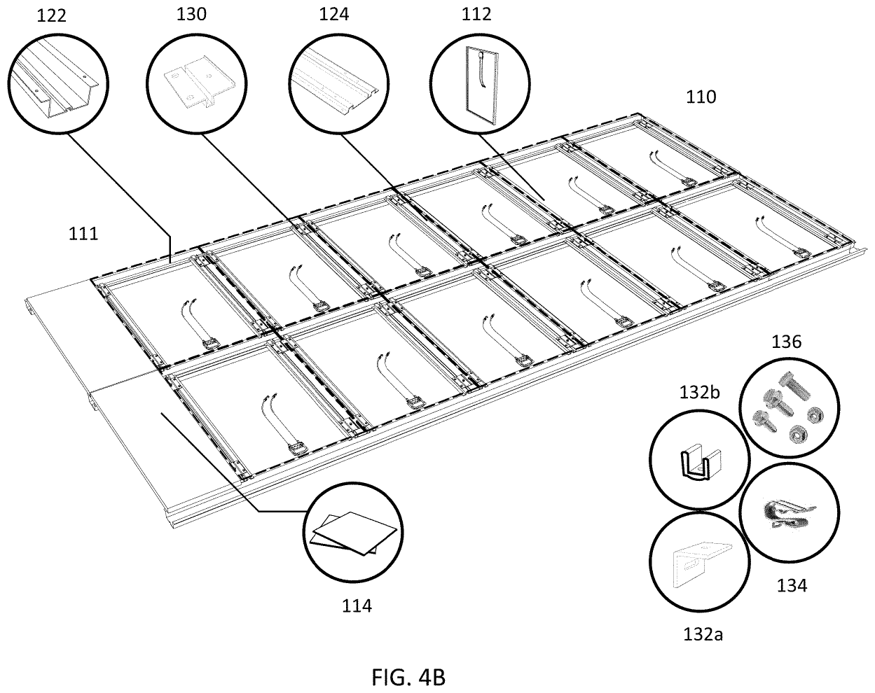

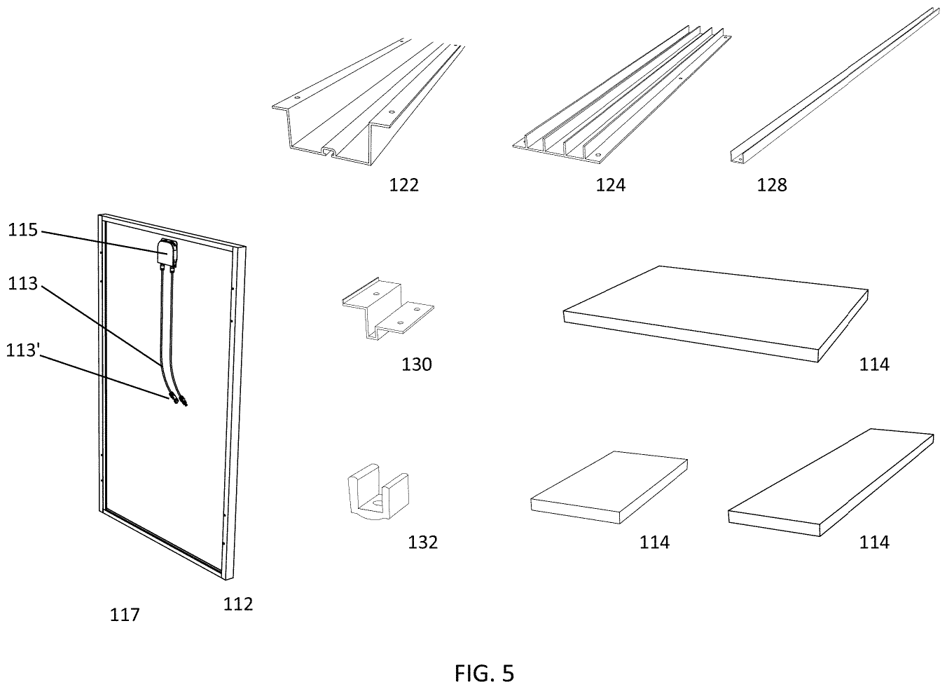

As described herein, the solar power generation assemblies can comprise integrated mounting and water management features. Assembly 100 can comprise a module mounting rail that also functions as a gutter for water drainage. As depicted in FIGS. 4A-4B and FIG. 5, system 100 comprises an assembly of parts including PV modules 112, panels 114, a first or mounting rail gutter 122, a second or “mini” gutter 124, a whip guide 128 for managing electrical whips 113 having connectors 113′ associated with module 112, and a module clip 130 for connecting modules to mounting rails and/or gutters. Many of these components may be optional or altered depending on desired configuration. An array attachment device 132 (e.g. a bent angle 132a or a purlin clip 132b, or any other desirable fastening device) can attach array 110 to purlin flanges 131 and/or support structures or beam(s) 107. Cable clips can 134 can function as cable management devices. Various fasteners 136 (e.g. bolts, screws, washers, nuts, rivets, self-tapping screws, fasteners with or without watertight sealants, etc.) and/or fastening support devices (e.g. bent plate angles 138) can fixedly couple the elements of the assembly 100 together. Many of these components may be optional depending on desired configuration. The above support, mounting, water management and cable management components can be made be of metals (e.g. aluminum), alloys (e.g. steel), plastics, composites or other structurally and functionally appropriate materials.

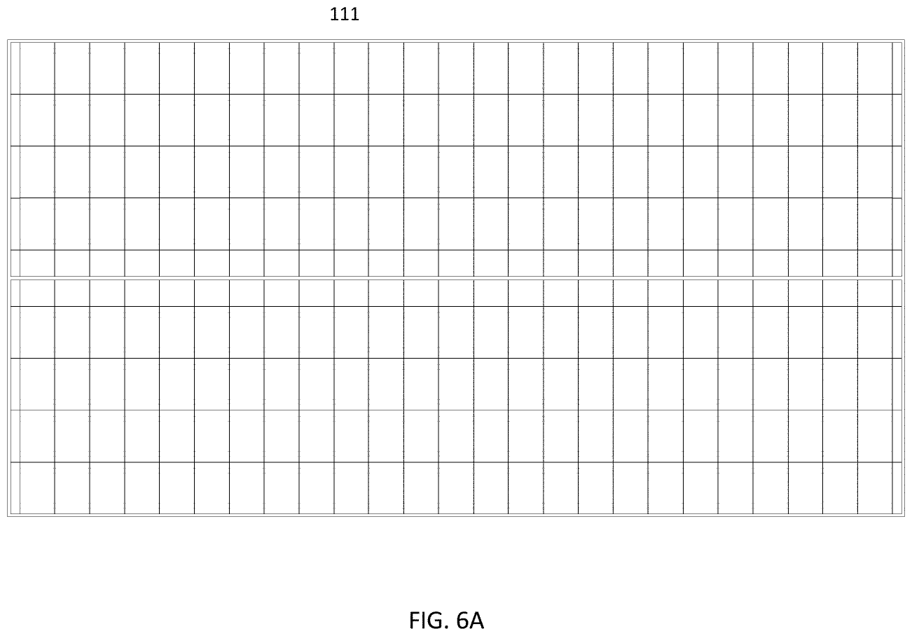

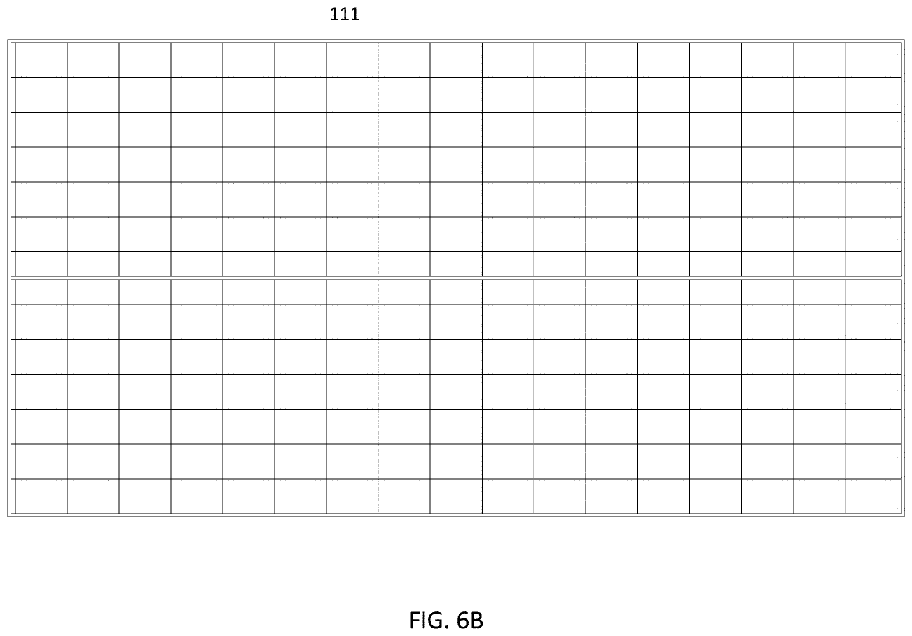

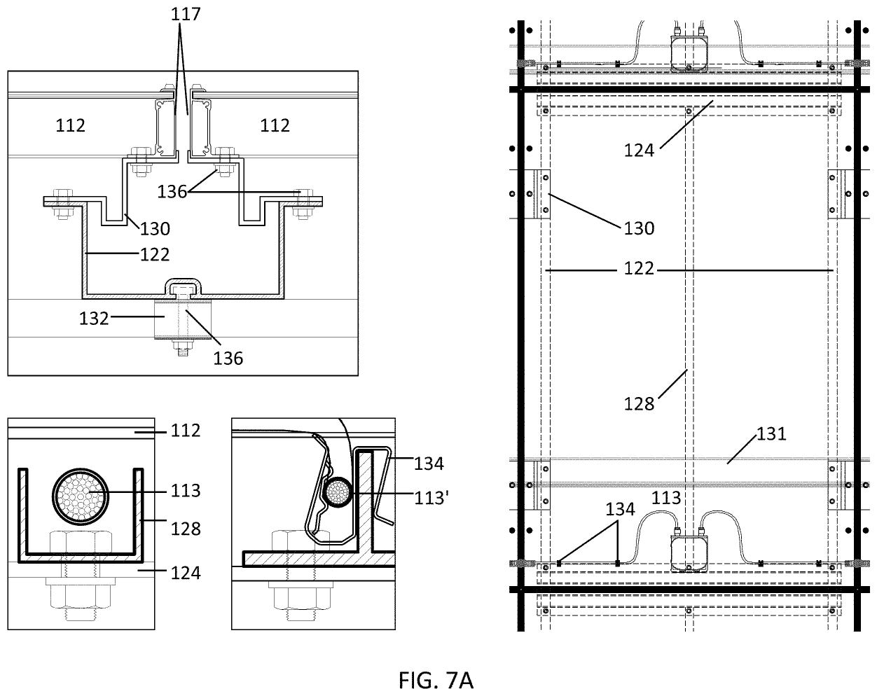

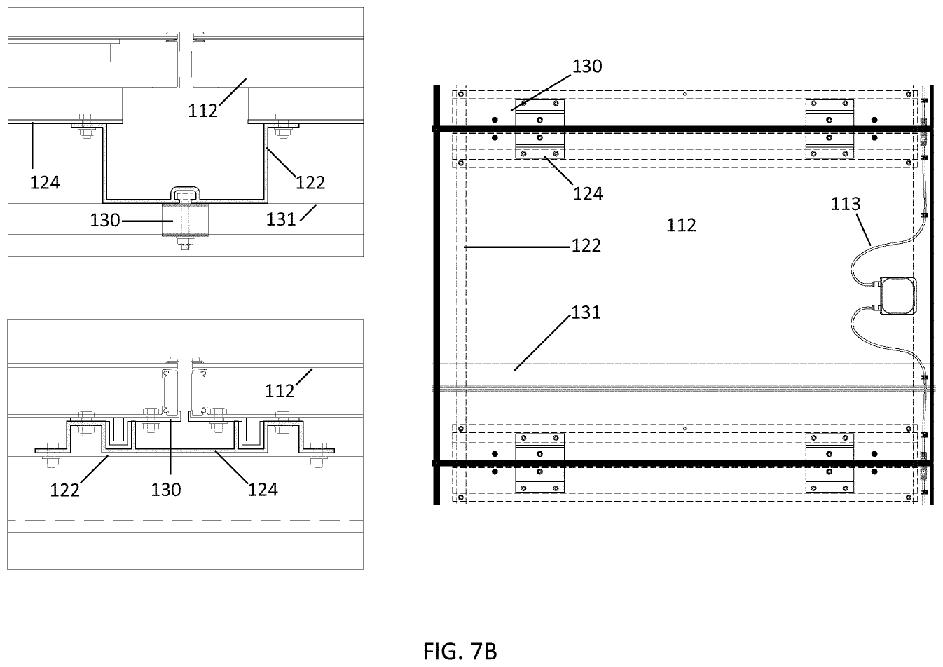

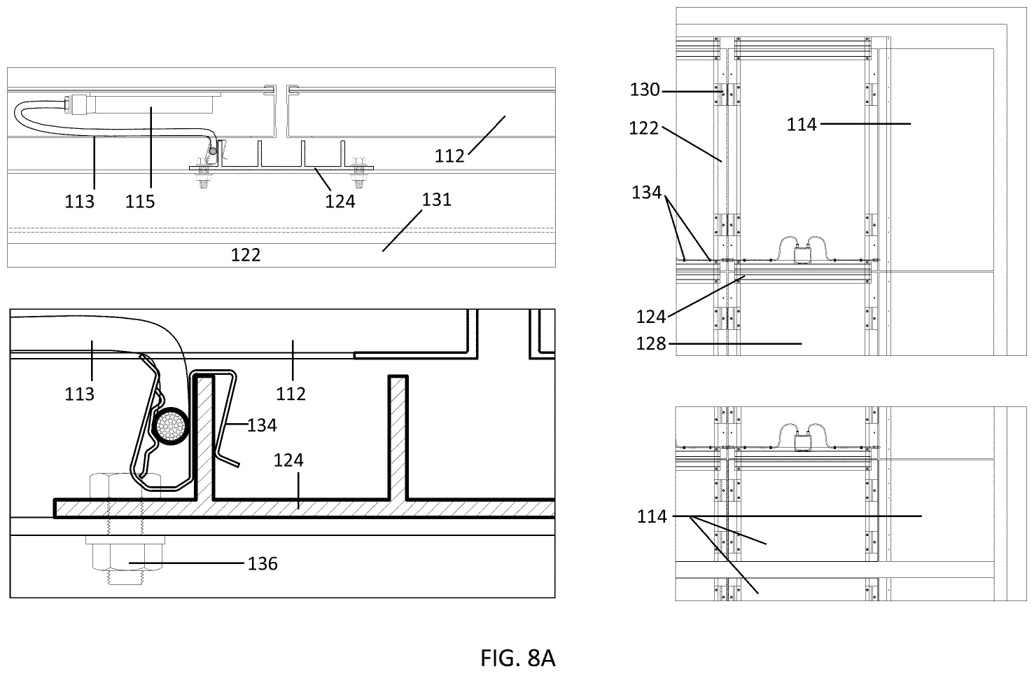

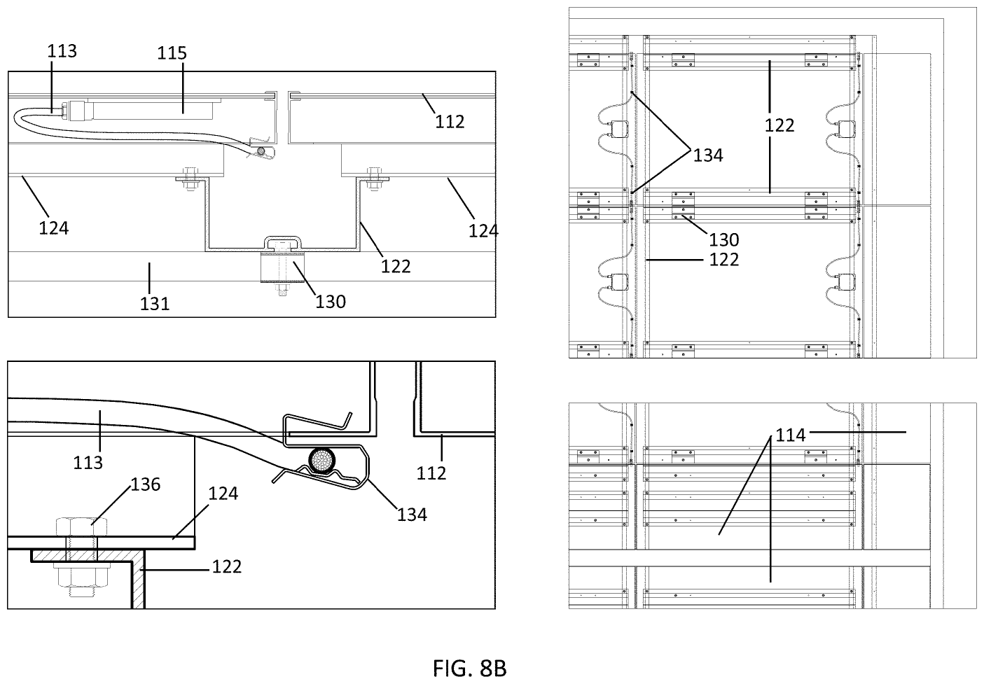

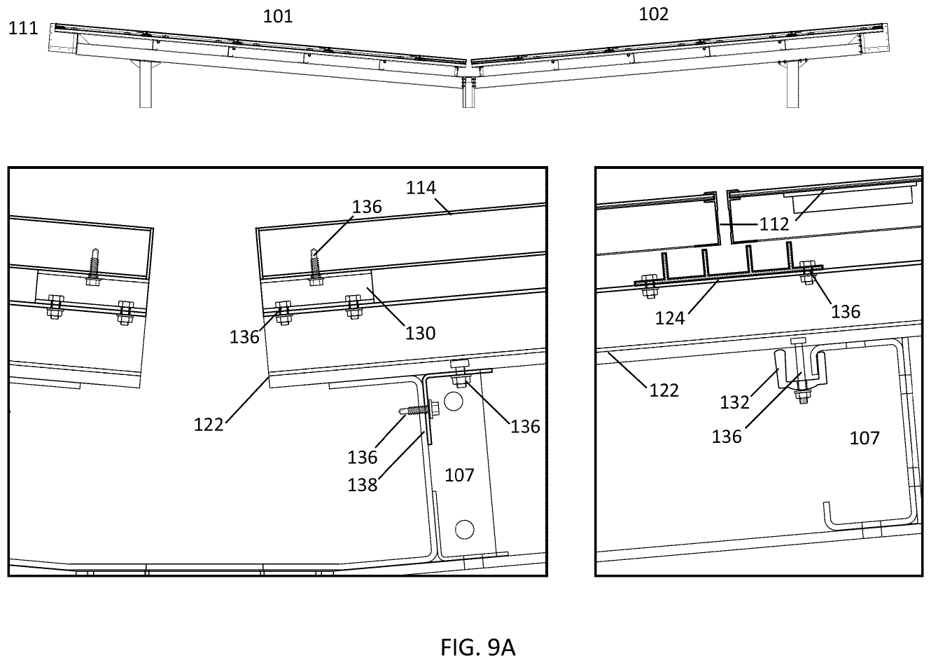

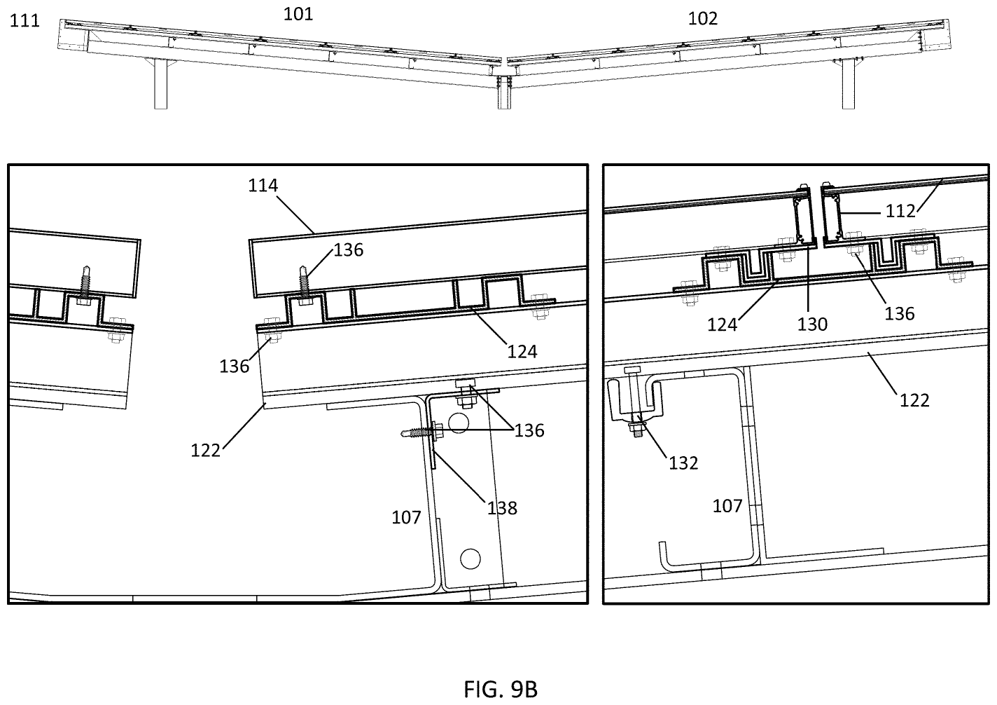

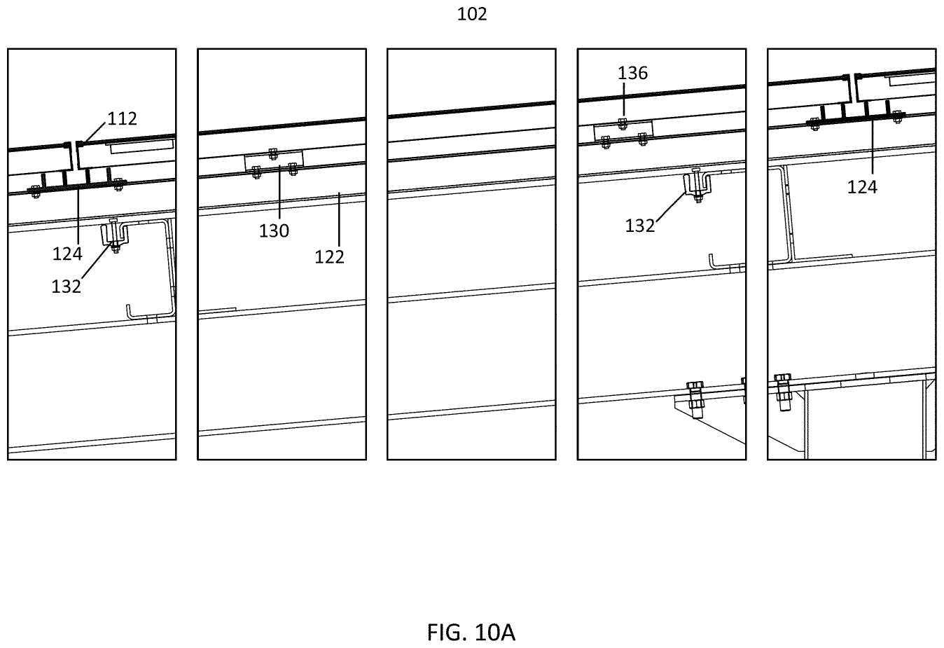

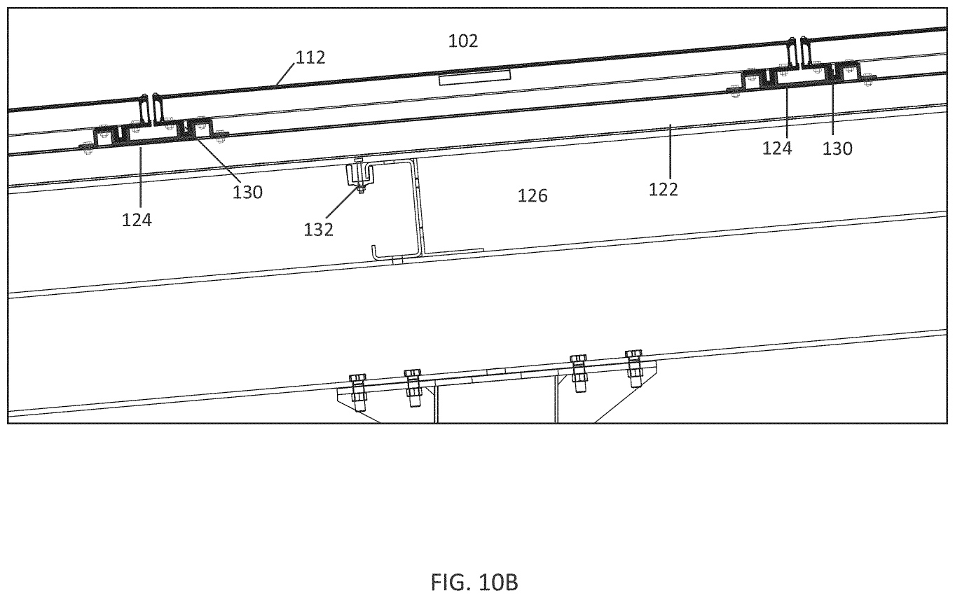

FIGS. 6A-B, 7A-B, 8A-B, 9A-B, 10A-B, and 11A-B depict various views of assembly or system 100 and the related assembly of components shown in 4A-B and FIG. 5. FIG. 6A-B depict a top-down view of assembly 100, whereas 7A-B, 8A-B, 9A-B, 10A-B, and 11A-B depict side and underside views of assembly 100.

In an embodiment, rail gutter 122 can comprise a cross-sectional profile having one or more open generally-“U” shaped structure so as to allow adjacent solar modules 112 to attach to the same rail gutter as well as collect and manage water that falls between adjacent modules 112 and/or leaks through frame 117 of module 112. Secondary gutter 124 can comprise a cross-sectional profile comprising a plurality of generally-“U” shaped structure as depicted herein.

In addition to the rail gutter 122 integrating mounting and water management features, the secondary or “mini” gutter 124 and the clip 130 provide both mounting and water management functionality. The clip 130 can elevate or lift modules 112 above the mounting rail so as to provide clearance between the top of the mounting rail gutter and bottom of the PV module. This clearance allows the secondary or “mini” gutter to be installed between adjacent PV modules in the other axis of the canopy. The secondary or “mini” gutter can thereby catch rain or precipitation falling between adjacent PV modules and a portion of rain falling on a PV module situated in a higher vertical direction.

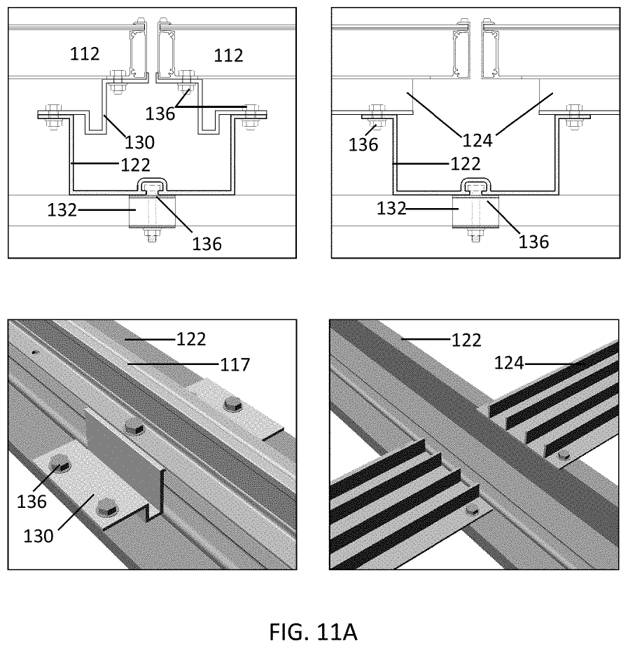

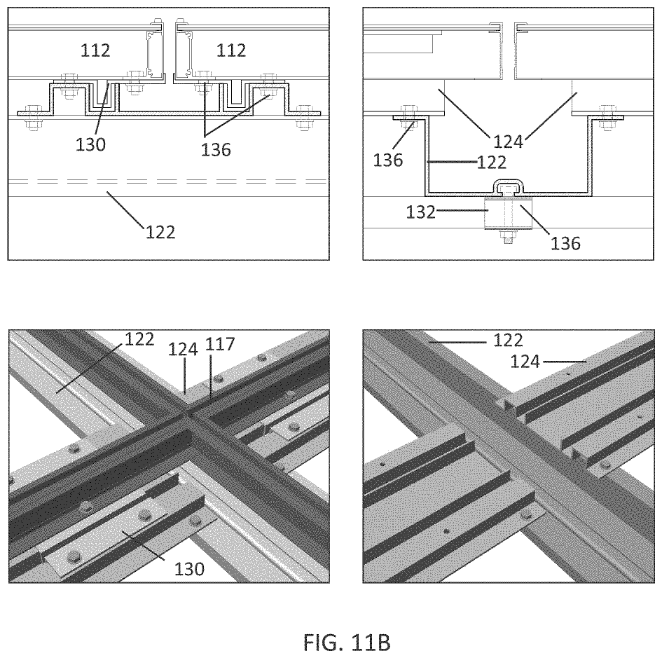

In one embodiment, the secondary or “mini” gutter can attach above the mounting rail gutter and extend over the top flange of the mounting rail gutter to transfer water into the mounting rail gutter such as depicted in FIG. 11A and FIG. 11B. However, other configurations are also possible. As another example, the secondary or “mini” gutter could attach below the mounting rail gutter and the central or main gutter can be configured to accept water from the secondary or “mini” gutters.

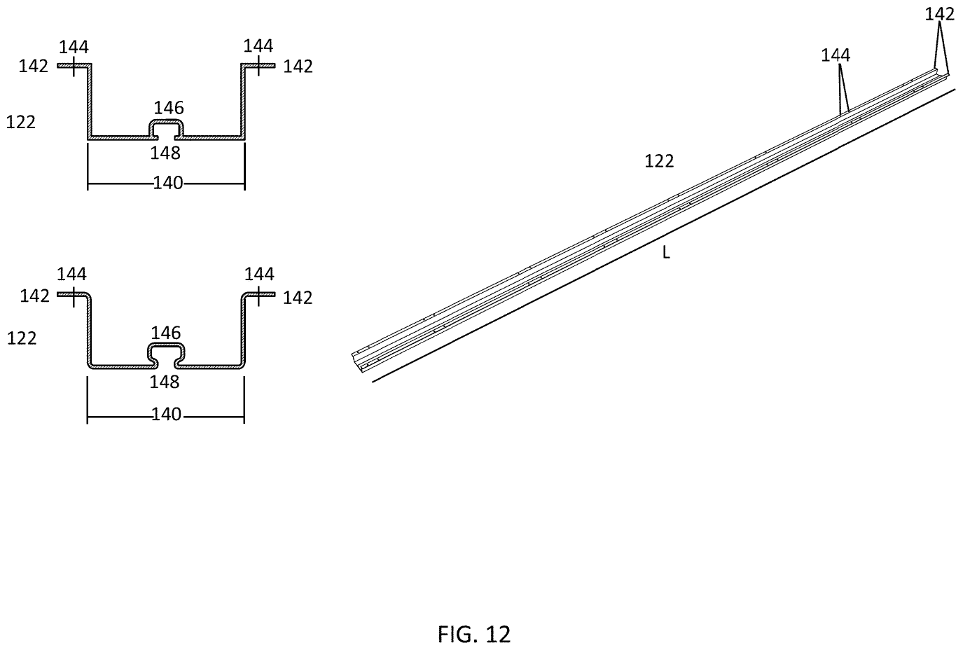

FIG. 12 depicts a side view and two cross-sectional views of rail gutter 122 according to some embodiments. Rail gutter 122 can be formed of as an aluminum extruded or roll formed part having a length L. As depicted in FIG. 12, rail gutter 122 can comprise a generally “U”-shaped body portion 140 between flanges 142. Flanges 142 can comprise holes, slots or openings 144 configured to accept fasteners 136 so as to fixedly couple the rail gutter to module clip 130 and/or PV module 112. The body portion 140 of rail gutter 122 can comprise an upward projection or fastener channel 146 forming a cavity 148 for accepting a fastener at the underside of gutter rail 122. The cavity 148 can be configured to accept a fastener so as to fixedly couple the rail gutter 122 to array attachment device 132 (e.g. a bent angle 132a or a purlin clip 132b).

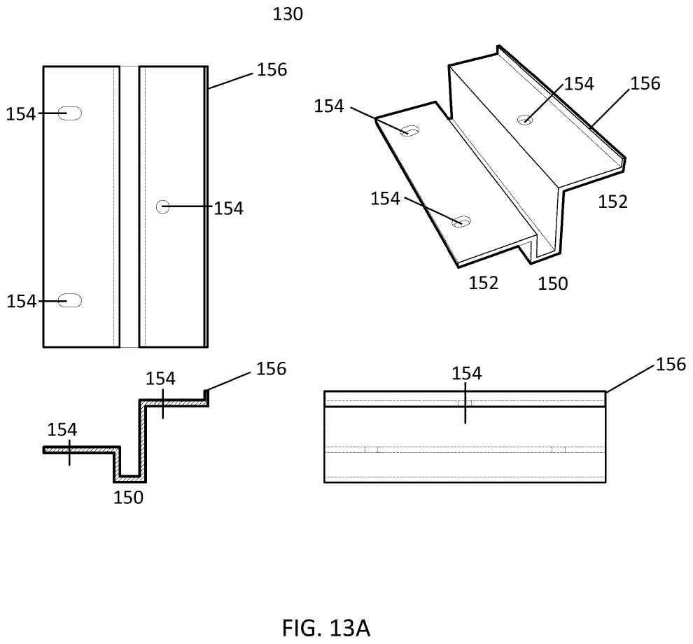

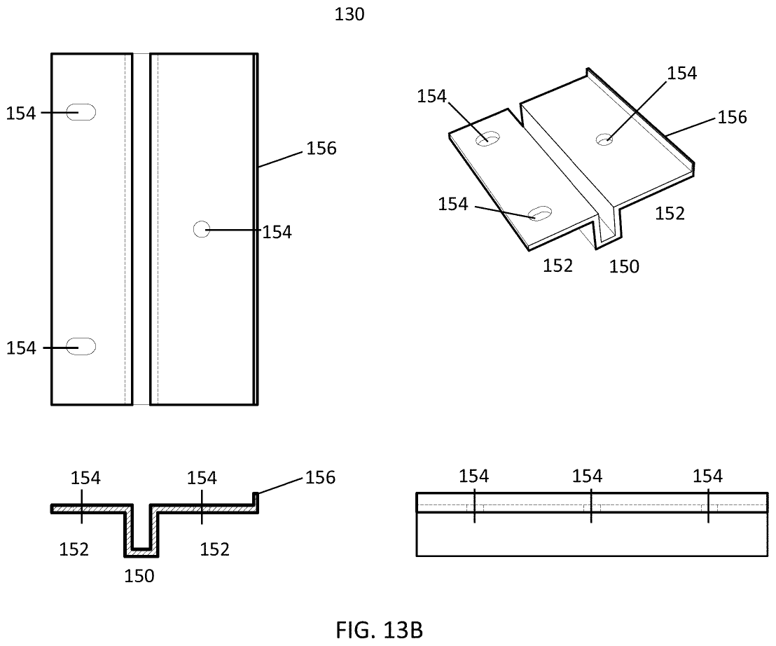

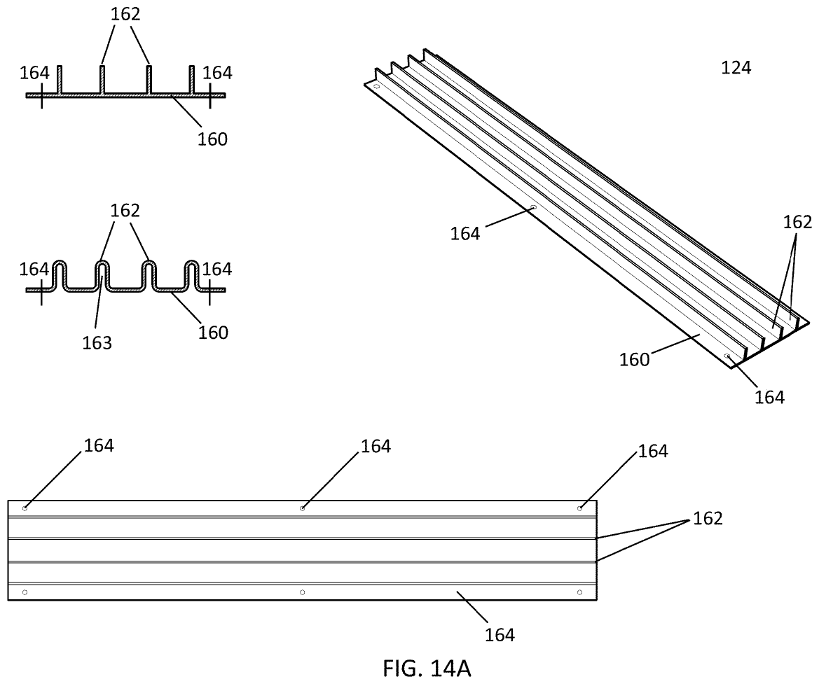

FIG. 13A and FIG. 13B show various views of module clip 130 according to some embodiments. The clip 130 comprises a generally “U”-shaped body portion 150 between flanges 152. Flanges 152 can comprise holes, slots or openings 154 configured to accept fasteners 136 so as to fixedly couple the rail gutter 122 and/or secondary gutter 124 to PV module 112. As depicted, the profile and shape of clip 130 is configured to inhibit or prevent any surface of the clip 130 from transferring precipitation out of a water collection area protected by the mounting rail gutter 122 and/or secondary gutter 124. Furthermore, the clip 130 comprises projections or “drip” edges 156 to direct precipitation into the rail gutter 122 and/or secondary gutter 124. The projections 156 can be configured to abut frame 117 of PV module 112. The relative dimensions of clip 130 can be modified as desired. For example, the clip 130 depicted in FIG. 13A comprises vertically offset flanges 152 so as to couple gutter rail 122 to PV module 112. As another example, the clip 130 depicted in FIG. 13B comprises flanges 152 without a vertical offset so as to couple secondary gutter 124 to PV module 112.

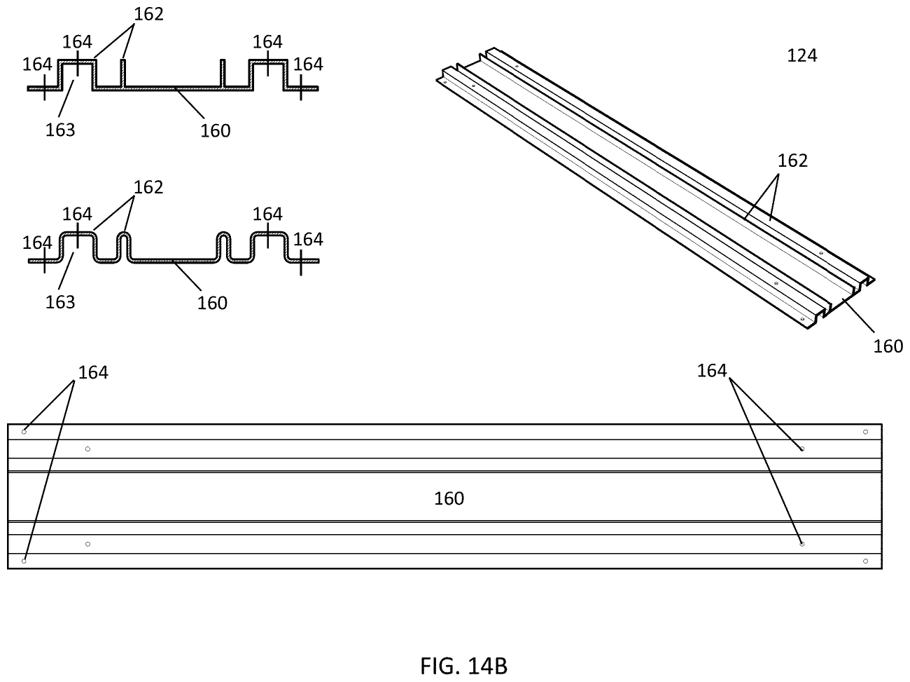

FIGS. 14A and 14B depict secondary or “mini” gutter 124 according to some embodiments. The secondary gutter 124 can comprise a fastening or base portion 160 and a plurality of longitudinally extending ridges or projections 162. The longitudinally extending projections 162 can form drainage channels for directing precipitation. The base portion 160 can comprise holes, slots or openings 164 configured to accept fasteners 136 so as to fixedly couple the secondary gutter 124 to rail gutter 124. Secondary gutter 124 can be stamped as a single piece or be roll formed. As depicted, projections 162 of secondary gutter 124 can be provided as a solid ridge, a hollow projection defined by a void 163, or a combination thereof. Furthermore projections 162 can comprise square or rounded edges. In the exemplary embodiments depicted in FIGS. 14A and 14B, four projections are provided, however any desirable number of projections and associated drainage channels can be provided.

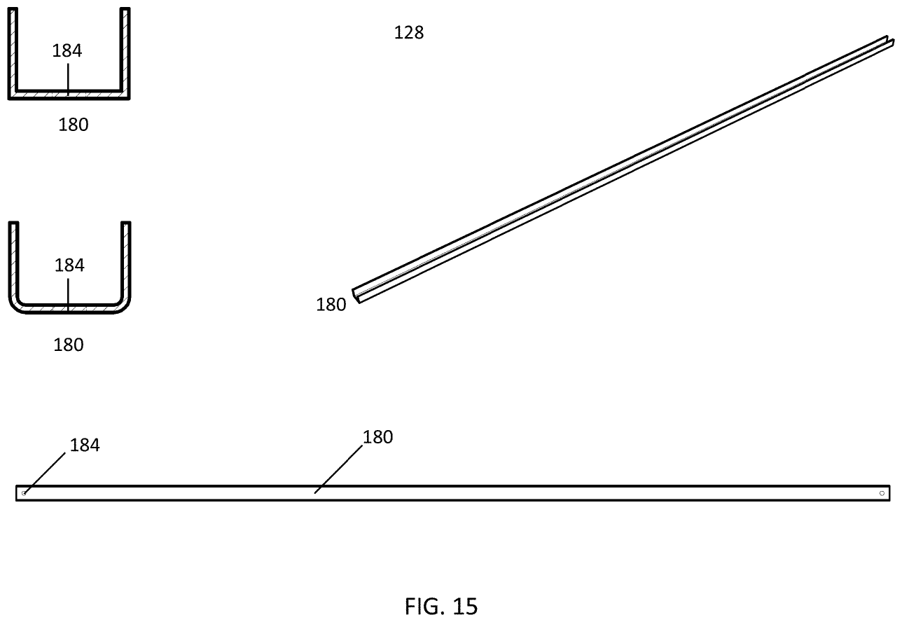

FIG. 15 depicts whip guide 128 according to some embodiments. Whip guide 128 can function to manage electrical whips 113 having connectors 113′ associated with module 112. Whip guide 128 can comprise a generally “U”-shaped body portion 180 having holes, slots or openings 184 configured to accept fasteners 136 so as to fixedly couple to rail gutter 122 and/or secondary gutter 124.

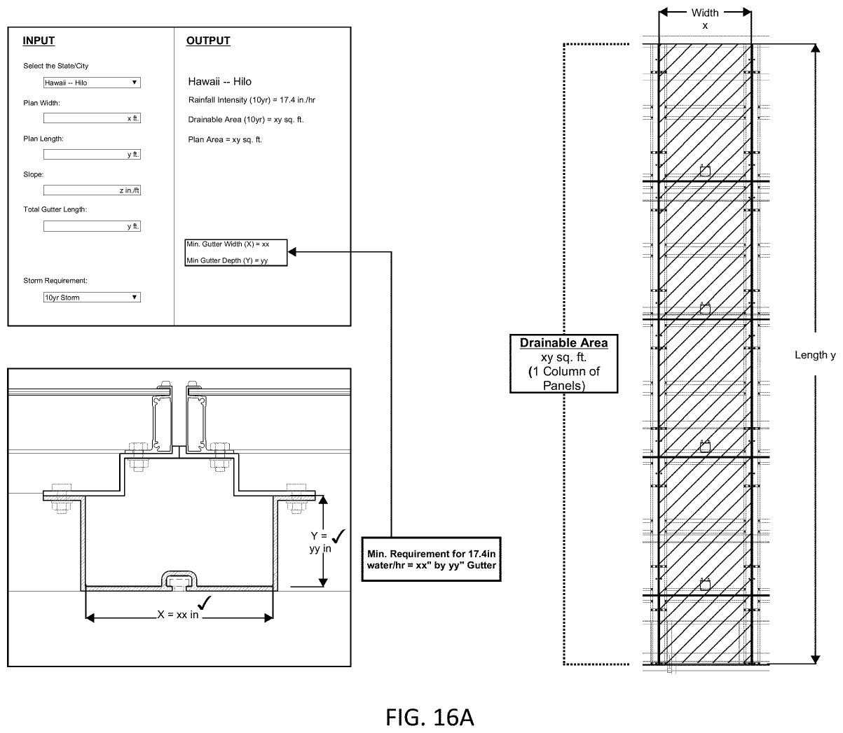

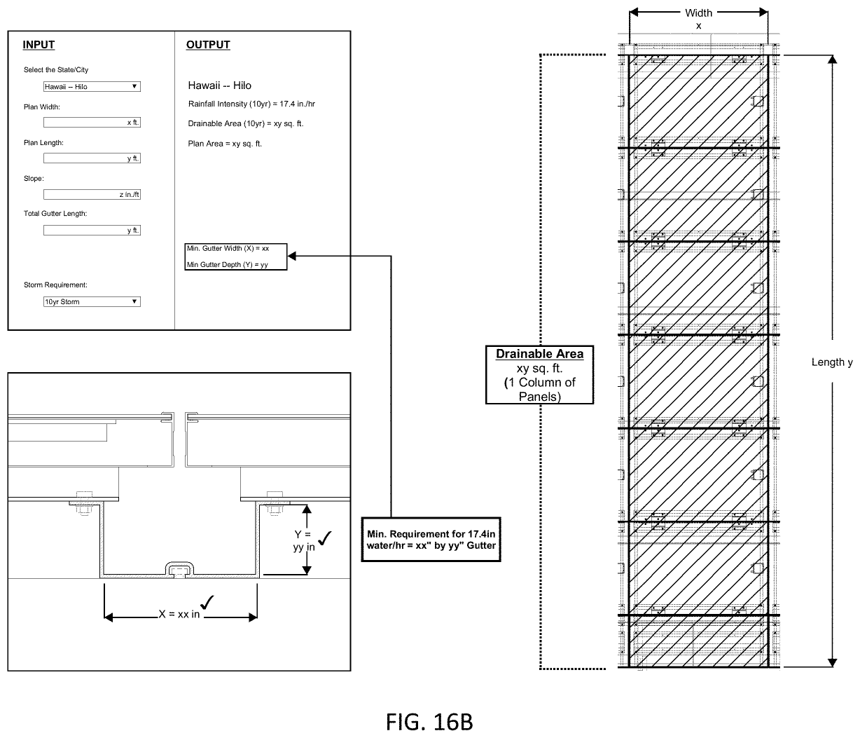

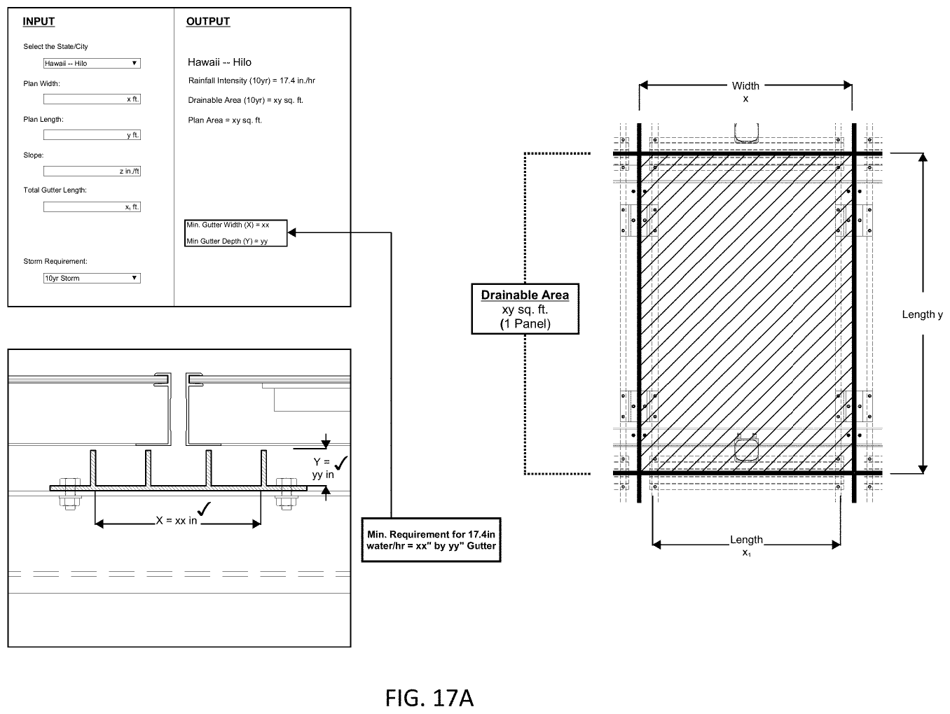

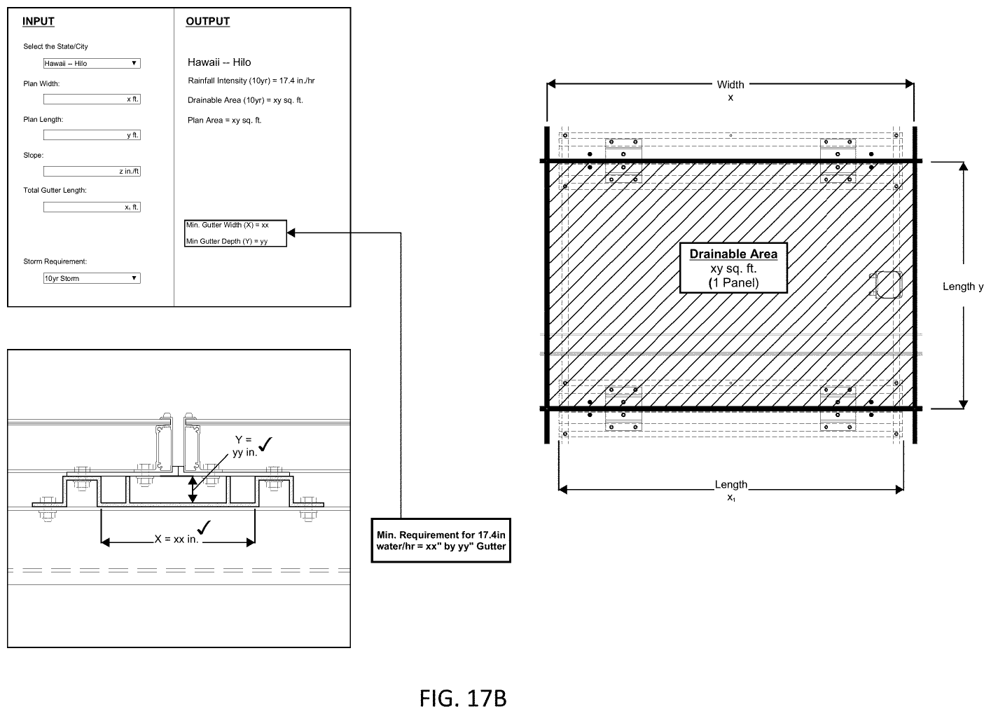

FIG. 16A, 16B, 17A, 17B depict operations for calculating and designing for an appropriate drainable area of system 100. For example, a geographic location can be selected (e.g. Hawaii) with a very high precipitation intensity as a baseline for sizing of the main gutter 120, mounting rail gutter 122 and/or secondary gutter 124. In the illustrative example, a ten year storm in the selected location (e.g. Hawaii) can produce water volumes of 17.4 inches of water per hour. A calculating operation can comprise inputting a surface area of the panels 112, 114 or array 110 a length of gutter for a specific system 100. A calculating operation can comprise outputting a required or optimal length and width of the main gutter 120, mounting rail gutter 122 and/or secondary gutter 124 profiles.

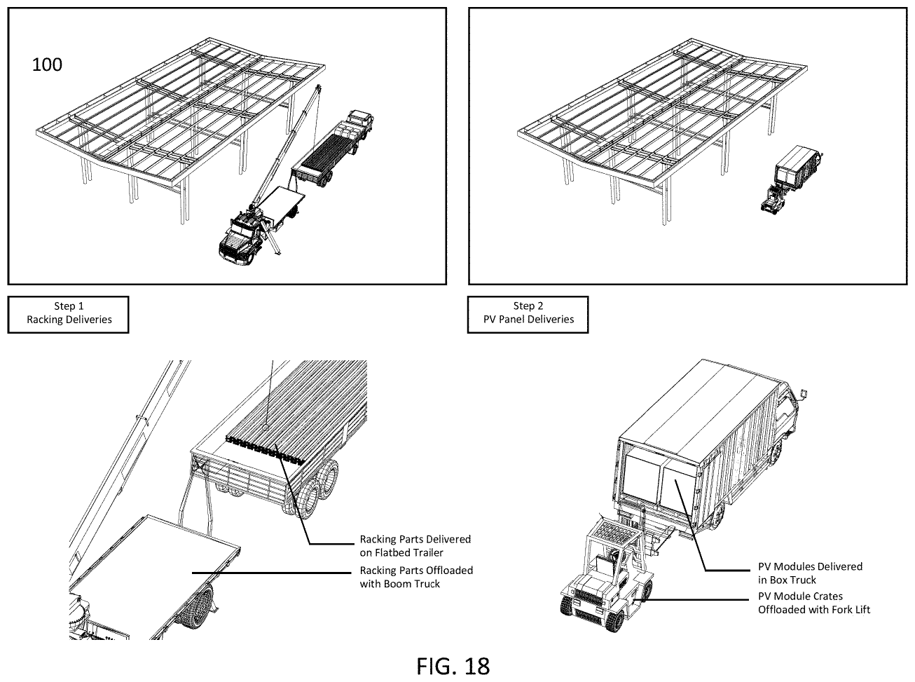

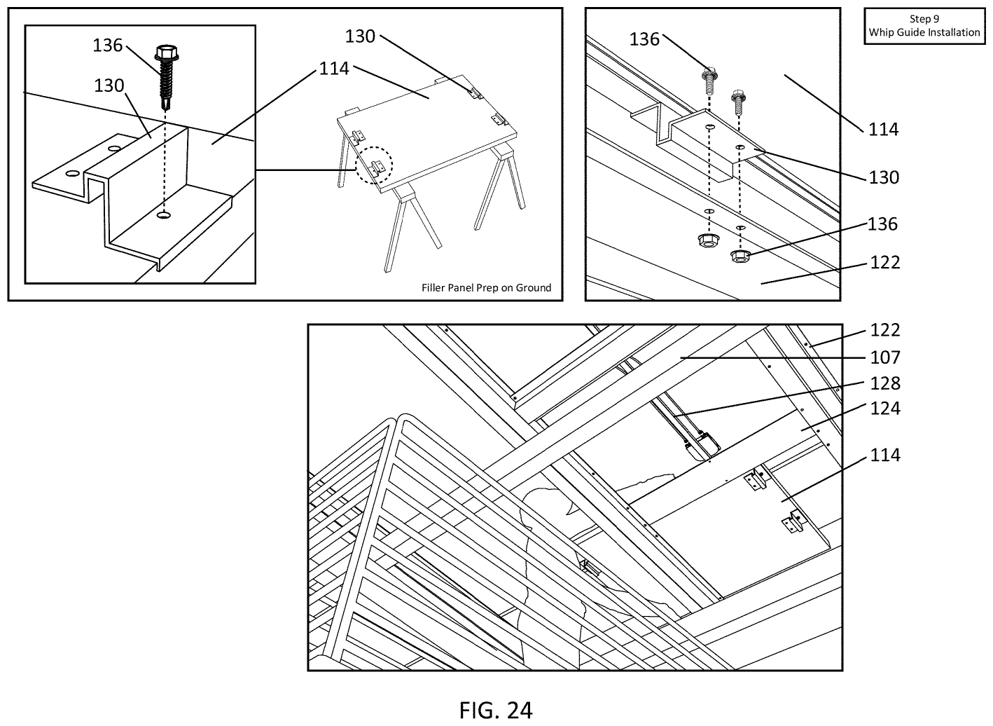

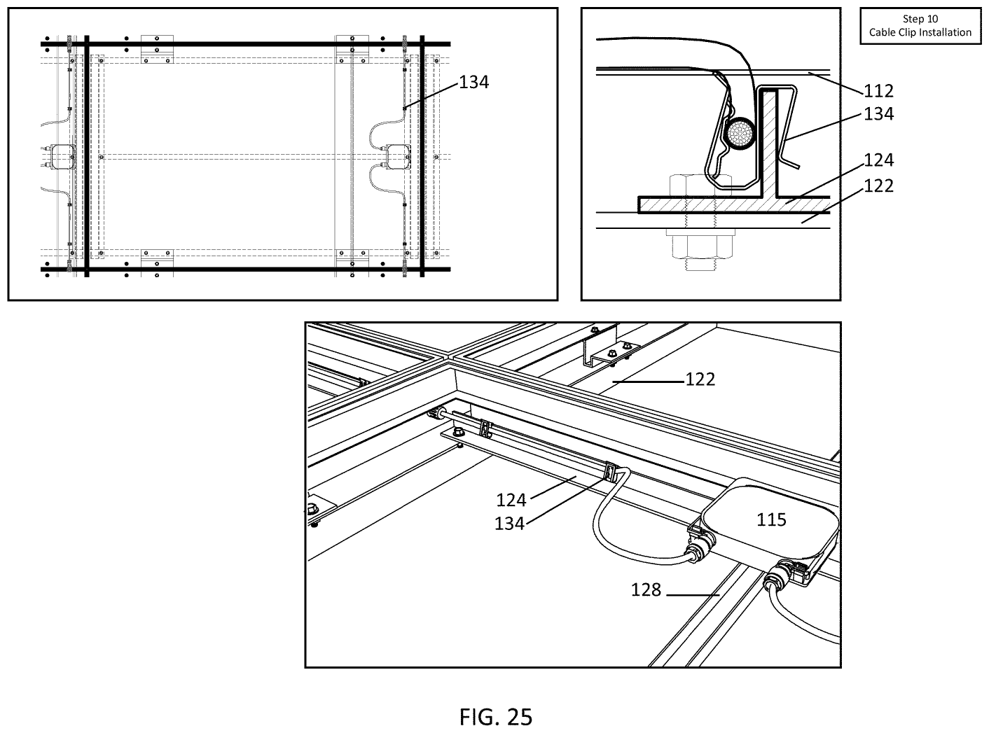

Improved methods of assembling or installing a solar power generation assembly with integrated mounting and water management are also described herein. FIG. 18-25 depict operations in a method of assembling or installing a solar power generation assembly, in accordance with an embodiment of the present disclosure. One or more of the disclosed operations can be optional and therefore can be omitted without departing from the scope of the invention described herein. The disclosed operations can occur in sequence and furthermore, in any suitable or desirable sequence or order. Additionally, two or more of the disclosed operations can occur simultaneously.

The assembly or system 100 is particularly advantageous in that it functions in a manner to allow installation from underneath the assembly 100 or canopy. The assembly 100 can be installed from below the canopy 101, 102, for example on scissor lifts or ladders. Installation from the underside is enabled at least in part by the fastener channel 146 located at the underside of mounting rail gutter 122. Fasteners 136 can be pre-loaded into cavity 148 of fastener channel 146 for each mounting rail gutter 122 while on the ground. Array attachment device 132 (e.g. a bent angle 132a or a purlin clip 132b) is configured so as to allow the mounting rail gutter 122 to be attached to the purlins or support beam(s) 107 from underneath the assembly 100. PV clips 130 can be installed on to the PV modules 112 on the ground and then hoisted on top of the mounting rail gutters 122 from below while portions of the mounting rail gutter 122 remain accessible from below for connecting fasteners to other components of the system.

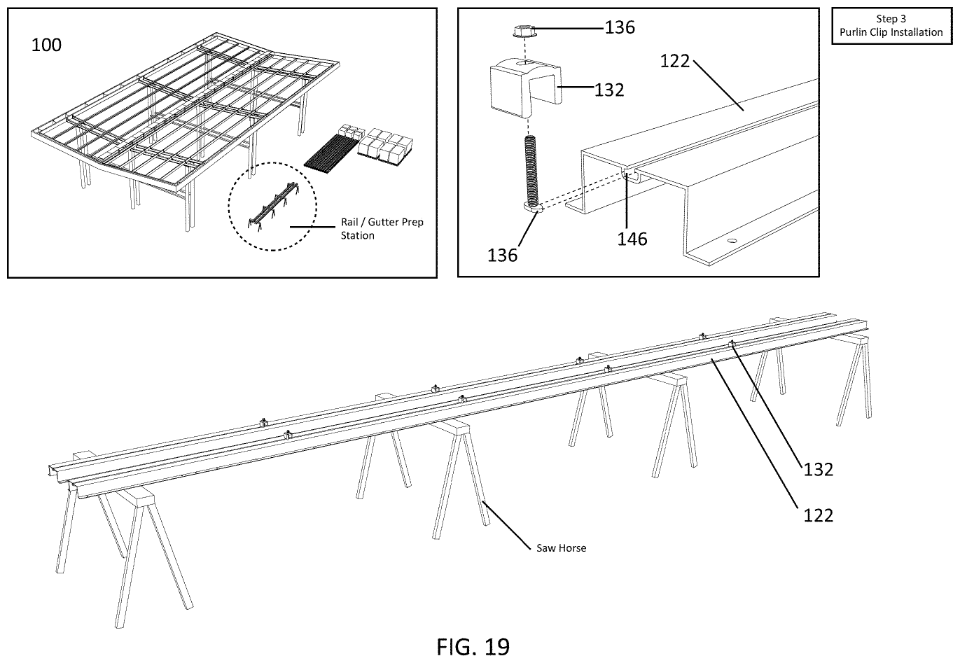

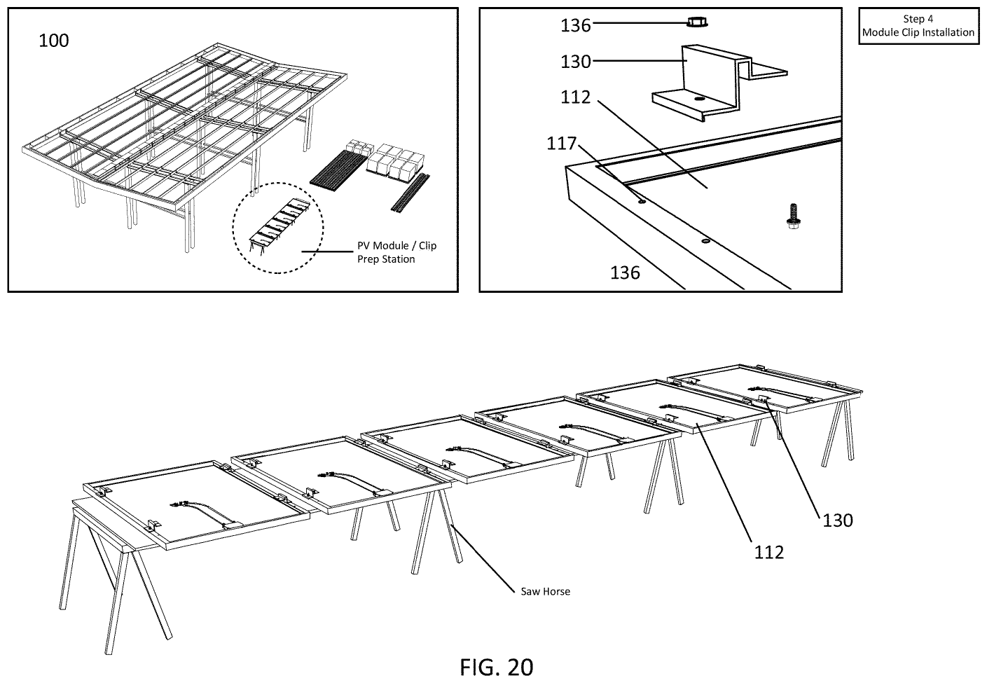

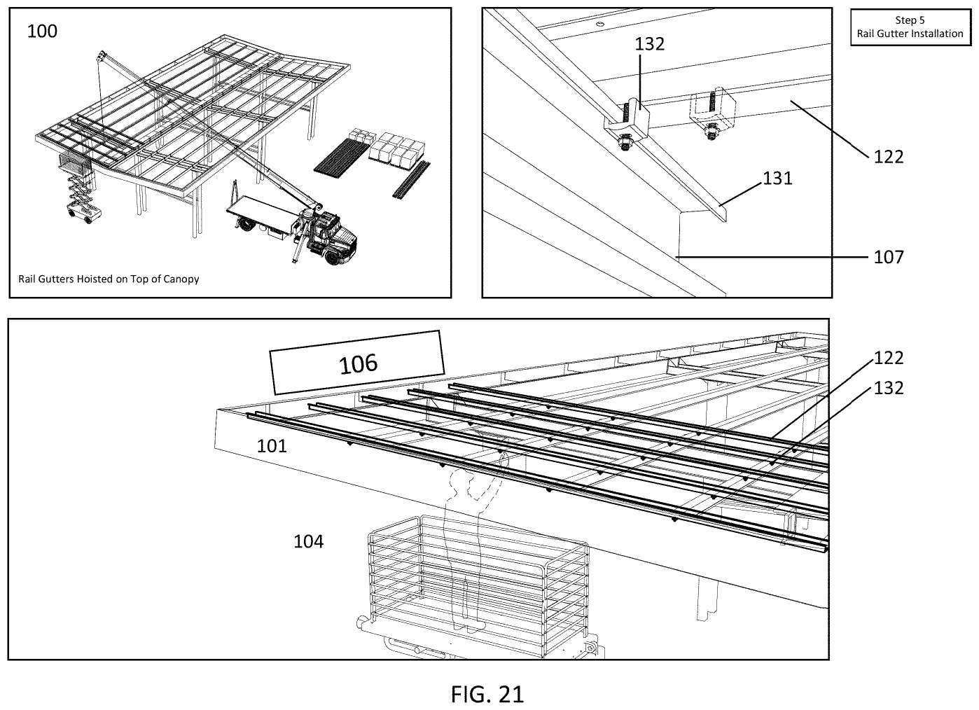

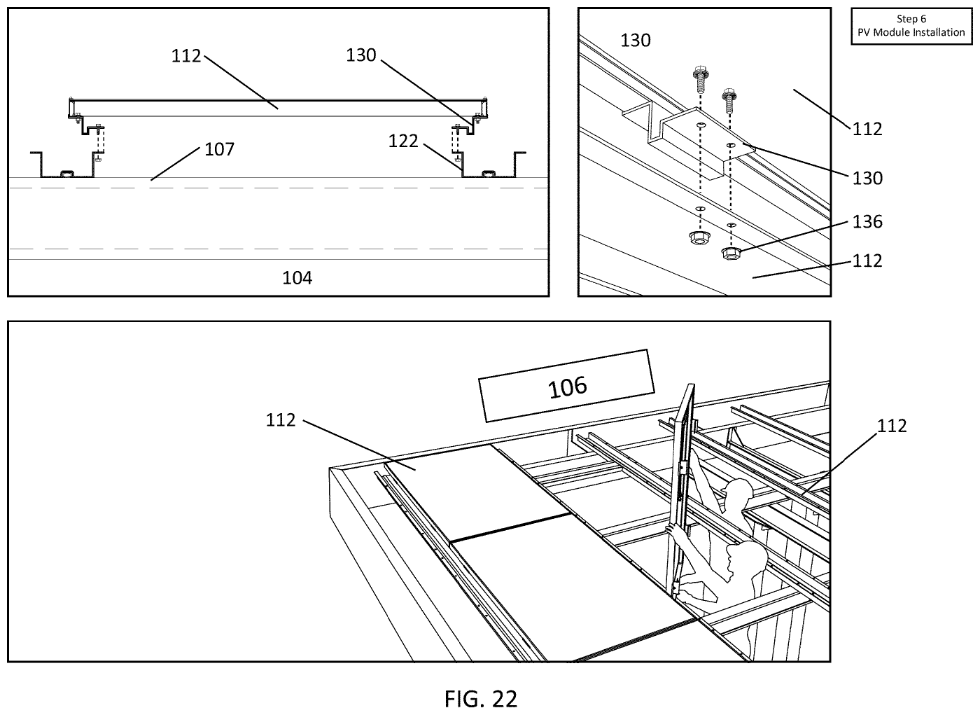

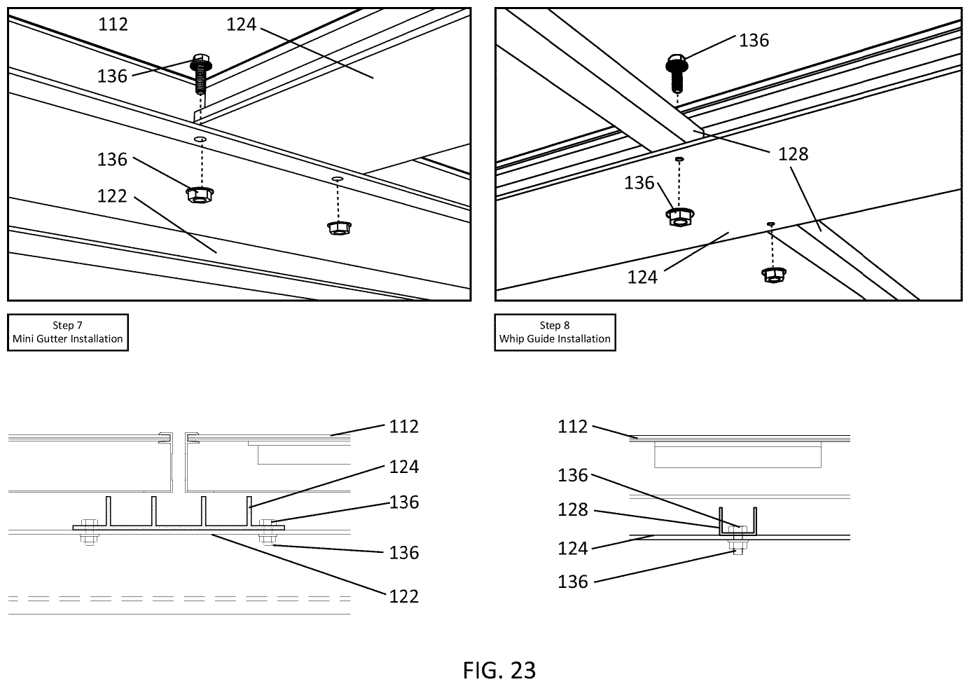

A method of assembling a solar power generation assembly can comprise the operation of providing at least one fastener 136 into a fastener channel 146 at the underside of said mounting rail gutter 122 as depicted in FIG. 19. The method can also comprise an operation of attaching at least one module clip 130 to solar module 112 as depicted in FIG. 20. The method can further comprise an operation of attaching a mounting rail gutter 122 to a first support structure 107 from an underside 104 of the solar power generation assembly 100 such as depicted in FIG. 21. The method can also comprise an operation of attaching a secondary gutter 124 to a mounting rail gutter 122 from an underside 104 of solar power generation assembly as depicted in FIG. 23. The method can further comprise an operation of mounting a solar module 112 above mounting rail gutter 122 and secondary gutter 124 from underside 104 of solar power generation assembly 100 via module clip 130 as depicted in FIG. 22-25.

The above specification and examples provide a complete description of the structure and use of illustrative embodiments. Although certain embodiments have been described above with a certain degree of particularity, or with reference to one or more individual embodiments, those skilled in the art could make numerous alterations to the disclosed embodiments without departing from the scope of this invention. As such, the various illustrative embodiments of the methods and systems are not intended to be limited to the particular forms disclosed. Rather, they include all modifications and alternatives falling within the scope of the claims, and embodiments other than the one shown can include some or all of the features of the depicted embodiment. For example, elements can be omitted or combined as a unitary structure, and/or connections can be substituted. Further, where appropriate, aspects of any of the examples described above can be combined with aspects of any of the other examples described to form further examples having comparable or different properties and/or functions, and addressing the same or different problems. Similarly, it will be understood that the benefits and advantages described above can relate to one embodiment or can relate to several embodiments. For example, embodiments of the present methods and systems can be practiced and/or implemented using different structural configurations, materials, and/or control manufacturing steps. The claims are not intended to include, and should not be interpreted to include, means-plus- or step-plus-function limitations, unless such a limitation is explicitly recited in a given claim using the phrase(s) “means for” or “step for,” respectively.

1. A solar power generation assembly comprising:
a first support structure;
a main gutter extending along a first longitudinal axis, the first longitudinal axis being along a longest dimension of the main gutter;
a first array comprising a plurality of solar modules;
a first mounting structure extending in a first plane above a ground surface, the first mounting structure being supported above the ground surface by the first support structure, the first array being coupled to the first mounting structure, the first mounting structure comprising at least one mounting rail gutter extending perpendicular to the main gutter in the first plane and configured to support the first array; and
at least one secondary gutter extending parallel to the main gutter in the first plane, the secondary gutter being positioned between adjacent solar modules of the plurality of solar modules in the first array and being configured to support the first array,
wherein the secondary gutter directs precipitation to the mounting rail gutter and the mounting rail gutter directs precipitation into the main gutter.

2. The solar power generation assembly of claim 1, wherein the solar power generation assembly further comprises a first canopy, and the first mounting structure is disposed on the first canopy.

3. The solar power generation assembly of claim 1, further comprising:
at least one module clip to mount at least one of the plurality of solar modules on the mounting rail gutter, the module clip being configured to be installed from an underside of the solar module.

4. The solar power generation assembly of claim 2, wherein the solar power generation assembly further comprises a second canopy and a second mounting structure, and the second mounting structure includes a second array comprising a plurality of solar modules disposed thereon.

5. The solar power generation assembly of claim 4, wherein the first and second canopies form a dual-incline structure.

6. The solar power generation assembly of claim 5, wherein the main gutter is disposed between the first and second canopies.

7. The solar power generation assembly of claim 1, wherein the secondary gutter is attached above the mounting rail gutter and extends over a top flange of the mounting rail gutter.

8. The solar power generation assembly of claim 1, wherein the at least one secondary gutter is attached below the mounting rail gutter and the main gutter.

9. The solar power generation assembly of claim 1, wherein a drainable area of the solar power generation assembly is sized based on a geographic location, and the geographic location corresponds to a predetermined estimate of precipitation.

10. The solar power generation assembly of claim 9, wherein a length and a width of one or more of the main gutter, the mounting rail gutter, and the secondary gutter is based on one or more of a surface area of the solar modules, a total gutter length for the solar power generation assembly, and the predetermined estimated precipitation.

11. A method for providing a solar power generation assembly, comprising:
providing at least one fastener into a fastener channel at an underside of a mounting rail gutter, the mounting rail gutter extending perpendicular to a main gutter in a first plane and is configured to support a first array comprising a plurality of solar modules;
attaching the mounting rail gutter to a first support structure from the underside of the solar power generation assembly, the first support structure supporting a first mounting structure extending in the first plane;
attaching a secondary gutter to the mounting rail gutter from the underside of the solar power generation assembly, the secondary gutter extending parallel to the main gutter in the first plane and configured to support the first array; and
mounting the first array above the mounting rail gutter and the secondary gutter from the underside of the solar power generation assembly,
wherein the secondary gutter directs precipitation to the mounting rail gutter and the mounting rail gutter directs precipitation into the main gutter.

12. The method of claim 11, wherein the solar power generation assembly further comprises a first canopy, and the method further comprises disposing the first mounting structure on the first canopy.

13. The method of claim 12, wherein the solar power generation assembly further comprises a second canopy and a second mounting structure, the second mounting structure includes a second array of solar modules disposed thereon, and the first and second canopies form a dual-incline structure.

14. The method of claim 11, further comprising:
attaching at least one module clip to at least one of a plurality of solar modules configured in the first array, the first array of solar modules being coupled to the first mounting structure.

15. The method of claim 11, wherein the main gutter extends along a first longitudinal axis in the first plane, and the first longitudinal axis is along a longest dimension of the main gutter.

16. The method of claim 11, further comprising attaching the secondary gutter above the mounting rail gutter, the secondary gutter extending over a top flange of the mounting rail gutter.

17. The method of claim 11, further comprising attaching the secondary gutter below the mounting rail gutter and the main gutter.

18. A solar power generation assembly, comprising:
a first canopy wing positioned at a first predetermined inclination;
a second canopy wing positioned at a second predetermined inclination, the first and second canopies forming a dual-incline structure and a main gutter is disposed between the first and second canopies;
at least one mounting rail gutter extending perpendicular to the main gutter and configured to support an array comprising a plurality of solar modules; and
a secondary gutter extending parallel to the main gutter and configured to support the array, wherein the secondary gutter directs precipitation to the mounting rail gutter and the mounting rail gutter directs precipitation into the main gutter.

19. The solar power generation assembly of claim 18, wherein one or more of the mounting rail gutter and the secondary gutter include a whip guide configured to manage electrical whips.

20. The solar power generation assembly of claim 18, wherein each of the mounting rail gutter and the secondary gutter are attached from an underside of the solar power generation assembly.
